(19) United States
(12) Patent Application Publication
(10) Pub. No.: US 2026/0087197 A1
(43) Pub. Date: Mar. 26, 2026

(54) PLANNING DEVICES, PLANNING METHODS, PLANNING PROGRAM

(71) Applicant: NTT, INC., Tokyo (JP)

(72) Inventors: Daichi ASAHI, Tokyo (JP); Ai HOSHINO, Tokyo (JP); Takahiro HATA, Tokyo (JP); Chihiro YAMAMOTO, Tokyo (JP); Masato KAMIYA, Tokyo (JP); Ippei SHAKE, Tokyo (JP)

(73) Assignee: NTT, Inc., Tokyo (JP)

(21) Appl. No.: 19/106,938

(22) PCT Filed: Sep. 5, 2022
(86) PCT No.: PCT/JP2022/033308

§ 371 Date: Feb. 26, 2025

(51) Int. Cl. G06F 30/20

(52) U.S. Cl. CPC G06F 30/20

(57) ABSTRACT

A planning device for planning a digital twin system including at least two digital twins. A planning device includes an overall arbitration unit that performs calculation of overall arbitration of an operation plan for an operation performed in a state where there is no operation of an object in a real space corresponding to each of the digital twins, and transmits a result of the overall arbitration to each of the digital twins, and a partial change unit that performs calculation of a partial change of the operation plan, by correction based on the result of the overall arbitration, for an operation performed in a state where there is an operation of an object in a real space corresponding to each of the digital twins, and transmits a result of the partial change to each of the digital twins.

### TECHNICAL FIELD

The disclosed technology relates to a planning device, a planning method, and a planning program.

### BACKGROUND ART

It has been conventionally studied to model an object or event existing in a real space on a computer and feed back a result of simulation performed on the computer to the real space. An object or event obtained by modeling the object or event existing in the real space on the computer will be hereinafter referred to as a digital twin or DT. A large number of objects exist in the real space and affect each other. This indicates that it is necessary to consider mutual influence between DTs.

For example, in Patent Literature 1, there is also a technology that proposes cooperation of a plurality of DTs related to town. This technology proposes that the DT activates on the condition of a set trigger, performs predictions and evaluations one after another, and optimizes the mutual influence.

### CITATION LIST

### Patent Literature

Patent Literature 1: WO 2022/102106 A

### SUMMARY OF INVENTION

### Technical Problem

However, a huge number of objects exist in the real space, and the reality progresses without waiting for the end of calculation for optimizing the mutual influence. Therefore, in a case where a plurality of conditions serving as triggers is set, if a plurality of calculations for optimizing the mutual influence is activated, the optimization calculation becomes complicated, and all the calculations may not be performed within a time required in the real world. Therefore, in order to efficiently operate each DT, a more efficient calculation method for adjusting mutual influence between DTs is required.

The disclosed technology has been made in view of the above points, and an object thereof is to provide a planning device, a planning method, and a planning program capable of efficiently creating a plan in consideration of mutual influence between digital twins.

### Solution to Problem

A first aspect of the present disclosure is a planning device for planning a digital twin system including at least two digital twins, the planning device including an overall arbitration unit that performs calculation of overall arbitration of an operation plan for an operation performed in a state where there is no operation of an object in a real space corresponding to each of the digital twins, and transmits a result of the overall arbitration to each of the digital twins, and a partial change unit that performs calculation of a partial change of the operation plan, by correction based on the result of the overall arbitration, for an operation performed in a state where there is an operation of an object in a real space corresponding to each of the digital twins, and transmits a result of the partial change to each of the digital twins.

A second aspect of the present disclosure is a planning method for planning a digital twin system including at least two digital twins, the planning method causing a computer to execute processing including performing calculation of overall arbitration of an operation plan for an operation performed in a state where there is no operation of an object in a real space corresponding to each of the digital twins, and transmitting a result of the overall arbitration to each of the digital twins, and performing calculation of a partial change of the operation plan, by correction based on the result of the overall arbitration, for an operation performed in a state where there is an operation of an object in a real space corresponding to each of the digital twins, and transmitting a result of the partial change to each of the digital twins.

A third aspect of the present disclosure a planning program for planning a digital twin system including at least two digital twins, the planning program causing a computer to execute processing including performing calculation of overall arbitration of an operation plan for an operation performed in a state where there is no operation of an object in a real space corresponding to each of the digital twins, and transmitting a result of the overall arbitration to each of the digital twins, and performing calculation of a partial change of the operation plan, by correction based on the result of the overall arbitration, for an operation performed in a state where there is an operation of an object in a real space corresponding to each of the digital twins, and transmitting a result of the partial change to each of the digital twins.

### Advantageous Effects of Invention

According to the disclosed technology, it is possible to create an efficient plan in consideration of mutual influence between digital twins.

### BRIEF DESCRIPTION OF DRAWINGS

FIG. 1 illustrates a schematic configuration example of the present embodiment.

FIG. 2 is a block diagram illustrating a hardware configuration of a planning device.

FIG. 3 is a block diagram illustrating an example of a functional configuration of the planning device.

FIG. 4 is an example of a configuration of a digital twin system configured in a planning system.

FIG. 5 is a sequence of overall arbitration.

FIG. 6 is a sequence of periodic partial changes.

FIG. 7 is a sequence of partial changes using DT as a trigger.

FIG. 8 is a flowchart illustrating a flow of planning processing of a planning device 10.

FIG. 9 is an example of a recommendation candidate.

FIG. 10 illustrates an image in a case of creating a combination of recommendations.

FIG. 11A is an example of purposes and evaluation contents of an objective function.

FIG. 11B is an example of purposes and evaluation contents of a constraint condition.

FIG. 12 is an example of a result of overall arbitration.

### DESCRIPTION OF EMBODIMENTS

Hereinafter, an example of an embodiment of the disclosed technology will be described with reference to the drawings. Note that, in the drawings, the same or equivalent components and portions are denoted by the same reference signs. In addition, dimensional ratios in the drawings are exaggerated for convenience of description, and may be different from actual ratios.

First, an outline of an embodiment of the present disclosure will be described. In the present embodiment, it is assumed to be operated in a digital twin computing (DTC) platform that extends the value of providing a plurality of digital twins (DT) in a chained manner.

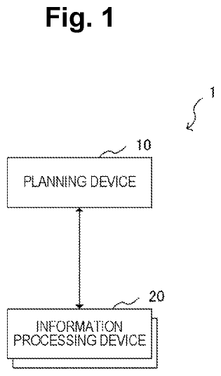

Hereinafter, a configuration of the present embodiment will be described. FIG. 1 illustrates a schematic configuration example of the present embodiment. FIG. 1 illustrates, as a planning system 1, a planning device 10 that creates and instructs a plan of a digital twin system, and a plurality of information processing devices 20 that provide various data to the planning device 10 and receive information from DT to perform respective processes. The planning device 10 is on a DTC/DT side, and the information processing device 20 is on an edge side. The planning device 10 in the planning system 1 is configured as a system that acquires plan information and actual result information in reality from all DTs, creates an overall plan, and gives an instruction to each DT (a specific example will be described later). The planning system 1 functions as an “overall arbitration/partial change DTC” that implements the above processing. Hereinafter, the DTC in the present embodiment refers to an overall arbitration/partial change DTC. Note that the digital twin system may be built inside the planning device 10 or may be built inside another device different from the planning device 10.

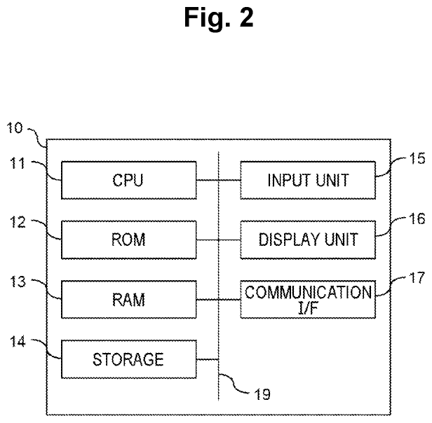

FIG. 2 is a block diagram illustrating a hardware configuration of the planning device 10. Note that the planning device 10 is not limited to a single device, and may be configured by a plurality of cloud environments on a cloud.

As illustrated in FIG. 2, the planning device 10 includes a central processing unit (CPU) 11, a read only memory (ROM) 12, a random access memory (RAM) 13, a storage 14, an input unit 15, a display unit 16, and a communication interface (I/F) 17. The components are communicatively connected to each other via a bus 19.

The CPU 11 is a central processing unit, and executes various programs and controls each unit. That is, the CPU 11 reads a program from the ROM 12 or the storage 14, and executes the program using the RAM 13 as a working area. The CPU 11 performs control of each of the components described above and various types of arithmetic processing in accordance with a program stored in the ROM 12 or the storage 14. In the present embodiment, a planning program is stored in the ROM 12 or the storage 14.

The ROM 12 stores various programs and various types of data. The RAM 13 is a working area that temporarily stores programs or data. The storage 14 includes a storage device such as a hard disk drive (HDD) or a solid state drive (SSD) and stores various programs including an operating system and various types of data.

The input unit 15 includes a pointing device such as a mouse and a keyboard and is used to perform various inputs.

The display unit 16 is, for example, a liquid crystal display and displays various types of information. The display unit 16 may function as the input unit 15 by employing a touch panel system.

The communication interface 17 is an interface for communicating with another device such as a terminal. For the communication, for example, a wired communication standard such as Ethernet (registered trademark) or FDDI, or a wireless communication standard such as 4G, 5G, or Wi-Fi (registered trademark) is used.

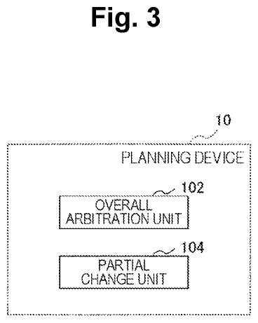

FIG. 3 is a block diagram illustrating an example of a functional configuration of the planning device 10.

As illustrated in FIG. 3, the planning device 10 includes an overall arbitration unit 102 and a partial change unit 104 as functional configurations. Each functional configuration is implemented by the CPU 11 reading a planning program stored in the ROM 12 or the storage 14, developing the planning program in the RAM 13, and executing the planning program.

The overall arbitration unit 102 calculates overall arbitration of an operation plan for an operation performed in a state where there is no operation of an object in the real space corresponding to each of the DTs, and transmits a result of the overall arbitration to each DT. The overall arbitration unit 102 creates a combination of recommendations by a predetermined optimization method in accordance with a predetermined objective function and a predetermined constraint condition by using each piece of acquisition information from each of the DTs, performs calculation of the overall arbitration, and notifies each of the DTs of a result of the overall arbitration. The combination of recommendations will be described later.

The partial change unit 104 calculates a partial change of the operation plan by correction based on the result of the overall arbitration for operation performed in a state where there is operation of an object in the real space corresponding to each of the DTs, and transmits a result of the partial change to each DT. The partial change unit 104 creates a combination of recommendations by correcting a difference from the operation plan of the combination of recommendations created in advance in accordance with a predetermined evaluation function and a predetermined constraint condition, performs calculation of the partial change, and notifies each of the DT of a result of the partial change. The partial change calculation is performed using each piece of acquisition information from DT, with a combination of recommendations based on the result of the overall arbitration as an initial combination.

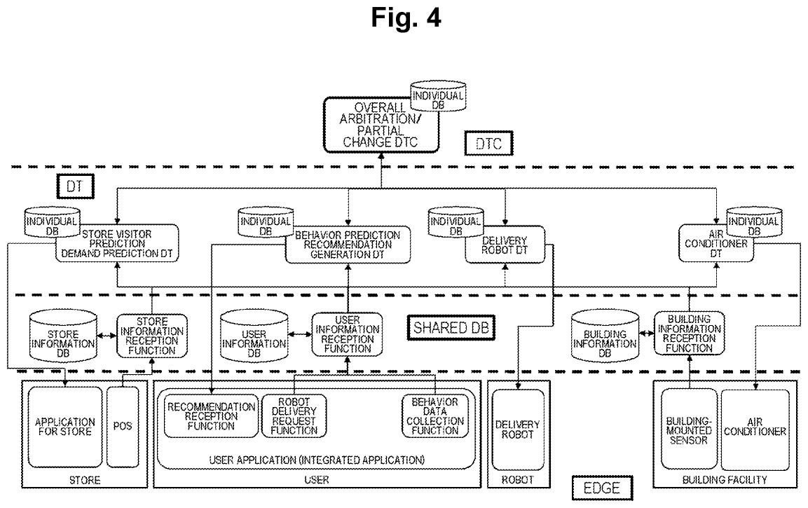

FIG. 4 is an example of a configuration of the digital twin system configured in the planning system 1. The digital twin system includes a DTC, a DT, a shared database (DB), and an edge. The planning device 10 creates an overall plan at two timings of overall arbitration and partial change in the system configuration of the digital twin system.

In the overall arbitration, the operation plan is calculated for the operation performed in a state where there is no operation of an object in the real space corresponding to each DT. The state where there is no operation is assumed to be, for example, nighttime to early morning. In the overall arbitration, the operation plans of all the DTs in which mutual influence has been adjusted are calculated from the plan information created by each DT. In the partial change, a plan change is performed for the operation performed in a state where there is operation of the object in the real space corresponding to each DT. In the partial change, a plan change is performed to correct a difference from the operation plan created by the overall arbitration by being activated under a set trigger condition from a measurement result of actual operation of the object in the real space corresponding to each DT.

A point of the method of the present embodiment is to create the overall operation plan in advance in the overall arbitration, that is, in a time slot in which there is no operation of the object in the real space corresponding to each DT. Then, the calculation performed in a state where there is operation of the object in the real space corresponding to each DT is reduced to only correction from the operation plan created in advance. Thus, calculation of adjustment of the mutual influence between DTs is made efficient.

Each component of the digital twin system will be described. Note that the DTC, DT, and shared DB are configured by the planning device 10, and the edge is configured by the information processing device 20.

The components of the edge include a store, a user, a robot, and a building facility.

The store has an application for the store and a point of sales (POS). The application for a store receives information from a store visit number prediction/demand prediction DT, and displays information such as store visitors, a predicted value of the demand number of each menu, an actual result value, and a discrepancy between predictions and actual results. In the POS, the actual sales result number of each menu of the store is acquired and sent to the store acquisition DB.

The user has a user application (integrated application) used by the user. The user application has a recommendation reception function, a robot delivery request function, and a behavior data collection function. The recommendation reception function has a function of displaying information received from a behavior prediction/recommendation generation DT. The robot delivery request function has a function of requesting delivery to the delivery robot DT. The behavior data collection function has a function of acquiring purchase, movement, eating and drinking, and environmental behavior and sending them to the user information DB.

The robot is a delivery robot. The delivery robot operates according to a command from the delivery robot DT.

The building facility has an air conditioner and a building-mounted sensor. The air conditioner operates according to a command from the air conditioner DT. The building-mounted sensor measures a flow of people (entrance and exit of people in each area), temperature, and the like, and sends the measured data to a building information DB.

Components of the shared DB include a store information DB, a user information DB, and a building information DB. Further, a store information reception function, a user information reception function, and a building information reception function are included as functions interposed between the respective DBs.

The store information DB stores information regarding a store. The information regarding the store is, for example, store basic information (store name, type, and the like), menu information (menu name, robot delivery availability, price, and the like), and sales information.

The user information DB stores information regarding the user. The information regarding the user is, for example, user basic information (age, gender, affiliation, and the like) and an action history (purchase, movement, food and drink, and environment).

The building information DB stores information regarding the building. The information regarding the building is, for example, building basic information (number of floors, users of each floor/area, and the like), flow of people, and other sensor data mounted on the building (temperature, humidity, and the like).

The DT includes a store visitor prediction/demand prediction DT, a behavior prediction/recommendation generation DT, a delivery robot DT, and an air conditioner DT. Note that the operation of each DT cooperating with an overall harmonic/partial change DTC will be described later.

The store visitor prediction/demand prediction DT predicts the number of store visitors, each menu, and the future demand number of each menu from data of the past flow of people to the store (the number of store visitors) of the building information DB and the past sales results of the store information DB. The store visitor prediction/demand prediction DT functions as, for example, a restaurant DT. The store visitor prediction/demand prediction DT is an example of a second digital twin for demand prediction of the present disclosure.

The behavior prediction/recommendation generation DT predicts behavior of each user using histories of purchase, movement, eating and drinking, and environmental behavior of the user information DB. The behavior prediction/recommendation generation DT generates a recommendation regarding when, where, what, and how the user behaves on the basis of prediction. The behavior prediction/recommendation generation DT functions as, for example, a lunch user DT. The lunch user DT predicts lunch behavior of the user and notifies the user of behavior to be taken. The behavior prediction/recommendation generation DT is an example of a first digital twin regarding behavior prediction of a user according to the present disclosure.

The delivery robot DT designates a moving place or the like from a delivery request received from the robot delivery request function, and gives an operation command to the delivery robot. The delivery robot DT is an example of a third digital twin related to the robot of the present disclosure.

The air conditioner DT creates an energy-saving operation plan for each area in the building using the past data of the flow of people to the store in the building information DB, and gives an operation command to the air conditioner. The air conditioner DT is an example of a fourth digital twin related to the air conditioner.

A DTC which is an overall arbitration/partial change DTC will be described. The DTC executes processing of the overall arbitration and partial change. Note that the processing executed by the DTC described below is processing executed by the planning device 10 as a DTC. Details thereof will be described below.

Processing of the overall arbitration will be described. The DTC receives a plurality of recommendation candidates of the target user from the behavior prediction/recommendation generation DT. Next, as the overall arbitration, the DTC generates an optimum combination of recommendations on the basis of constraint/target values received from the store visitor prediction/demand prediction DT, the delivery robot DT, and the air conditioner DT. As the overall arbitration, the DTC returns the generated combination of recommendations to each DT. The combination of recommendations is a combination of recommendation to the user in the behavior prediction/recommendation generation DT and an operation plan of another digital twin other than the behavior prediction/recommendation generation DT.

Processing of the partial change will be described. The DTC acquires data of a progress status from each DT to the present periodically or at the timing of notification from each DT. The DTC reconfigures a combination of recommendations on the basis of the acquired data. The reconfigured combination of recommendations is returned to each DT.

Next, the operation of the planning device 10 will be described.

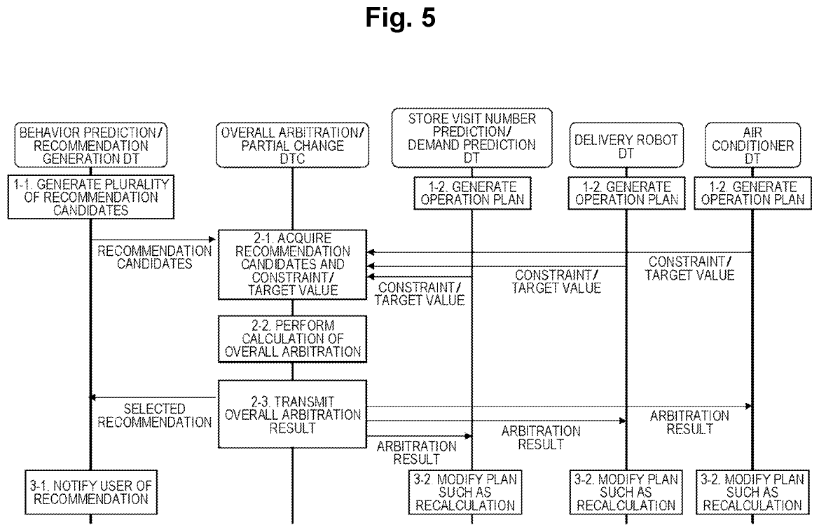

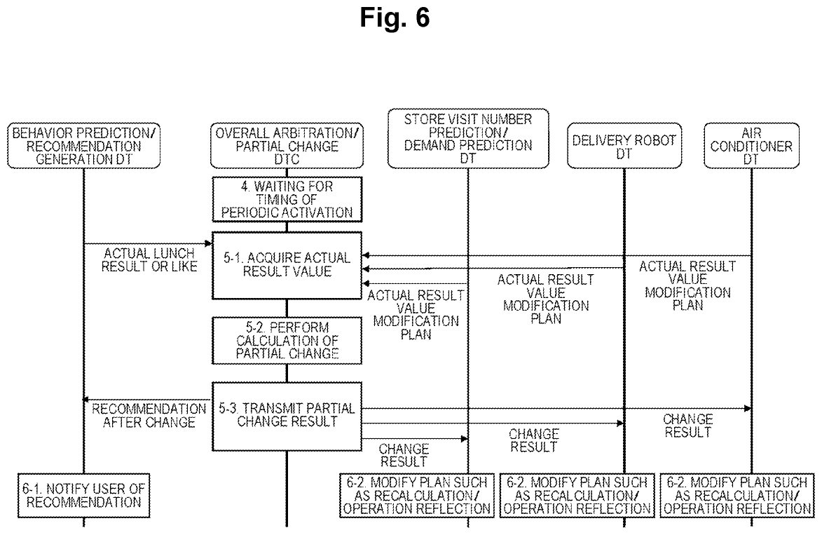

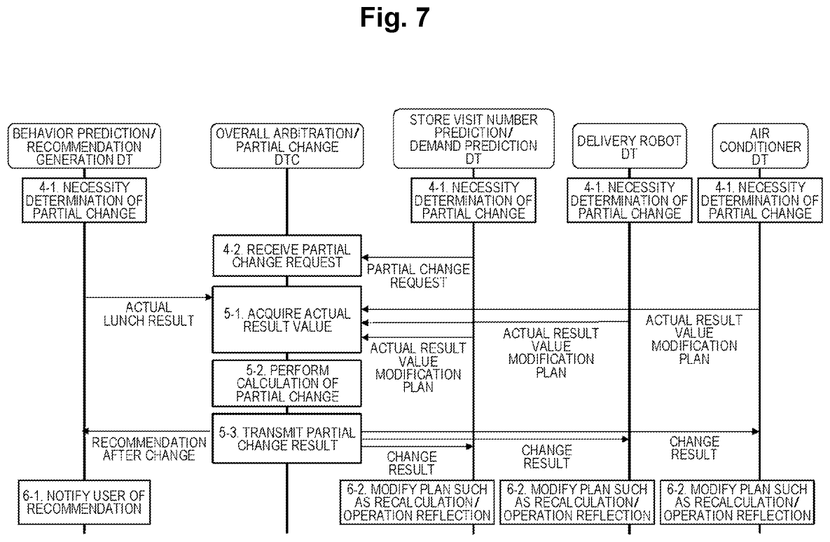

FIGS. 5 to 7 are sequences illustrating flows of processing in the digital twin system. FIG. 5 is a sequence of the overall arbitration. FIG. 6 is a sequence of periodic partial change. FIG. 7 is a sequence of partial change using the DT as a trigger.

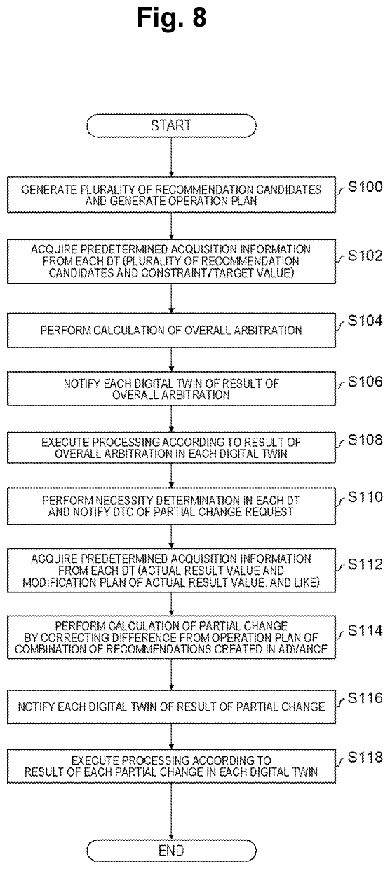

FIG. 8 is a flowchart illustrating a flow of planning processing of the planning device 10. The flowchart of the planning processing is obtained by replacing the above sequence with the flow of the planning processing executed as the planning device 10. The planning processing is executed by the CPU 11 reading the planning program from the ROM 12 or the storage 14, loading the planning program into the RAM 13, and executing the planning program.

First, a sequence of the digital twin system will be described. In the sequence, the overall arbitration corresponds to a flow of 1 to 3 and the partial change corresponds to a flow of 4 to 6.

The sequence of the overall arbitration of FIG. 5 will be described. 1-1 is processing of behavior prediction/recommendation generation DT. 1-2 is processing of other DTs of the store visitor prediction/demand prediction DT, the delivery robot DT, and the air conditioner DT (hereinafter, described as other DTs) other than the behavior prediction/recommendation generation DT.

In 1-1, the behavior prediction/recommendation generation DT generates a plurality of recommendation candidates. The behavior prediction/recommendation generation DT predicts behavior of each user using histories of purchase, movement, eating and drinking, environmental behavior, and preference information of the user information DB. The behavior prediction/recommendation generation DT generates a plurality of recommendation candidates regarding when, where, what, and how the user behaves on the basis of the prediction.

In 1-2, the other DTs generate each operation plan. The store visitor prediction/demand prediction DT predicts the number of store visitors, each menu, and the future demand number of each menu from data of the past flow of people to the store (the number of store visitors) of the building information DB and the past sales results of the store information DB. The delivery robot DT predicts/calculates the number of orders that can be accepted by the delivery robot at each time from a past operation history of the delivery robot. The air conditioner DT performs human flow prediction from past human flow data, and creates an operation plan of an air conditioner according to a predicted human flow.

In 2-1, the DTC acquires a plurality of recommendation candidates from the behavior prediction/recommendation generation DT and a constraint/target value from the other DTs as acquisition information.

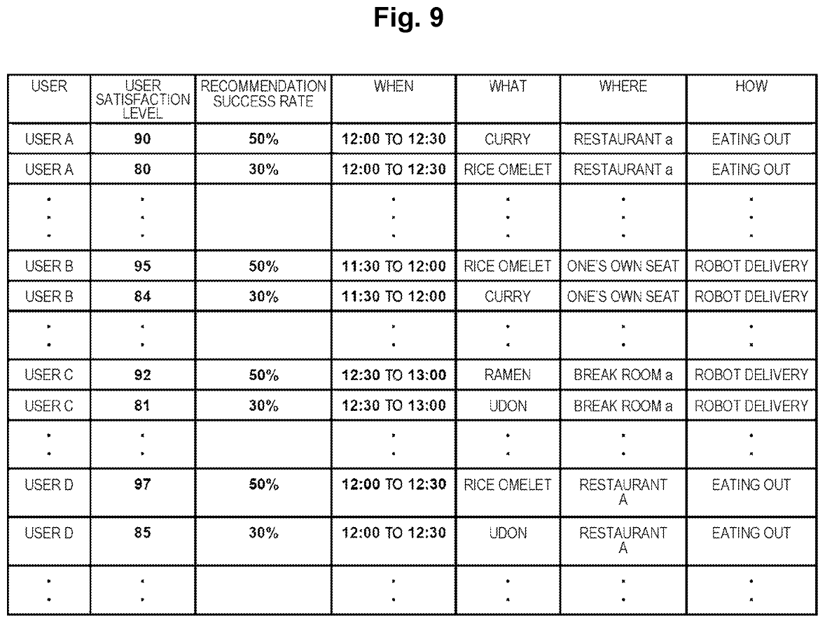

FIG. 9 is an example of a recommendation candidate. The items of the recommendation candidates in FIG. 9 include a user, a user satisfaction level, a recommendation success rate, when, what, where, and how. The recommendation candidate is generated as a plurality of proposals of recommendation to each user combining these items. A higher value of the user satisfaction level is more desirable for the user.

Examples of other constraint/target values of DT will be described. In an output of the store visitor prediction/demand prediction DT, the accommodatable number of people in each store (restaurant) is used as a constraint, a value of store visitor prediction for each restaurant is used as a target value, and a value of demand prediction of a product is used as a target value. The target value is, for example, a value such as “prediction of store visitors to restaurant A: 20 customers, prediction of demand number for curry: 10 servings, prediction of demand number for omelet rice: 10 servings, prediction of store visitors to restaurant B: 20 customers, prediction of demand for ramen: 10 servings, or prediction of demand for noodles: 10 servings”.

In the output of the delivery robot DT, the number of orders that can be accepted in each time slot is used as a constraint. The constraint is expressed as, for example, “11:30 to 12:00/8, 12:00 to 12:30/9, 12:30 to 13:00/9”.

In 2-2, the DTC performs calculation of the overall arbitration.

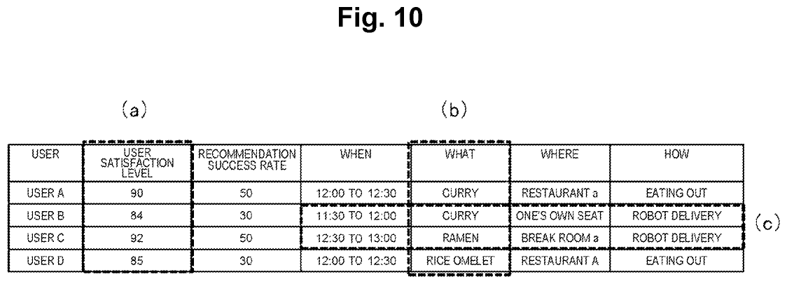

FIG. 10 illustrates an image in a case of creating a combination of recommendations.

The DTC selects a recommendation of each user from a list of recommendation candidates acquired from the behavior prediction/recommendation generation DT, and creates a combination of recommendations of all users. The combination of recommendations is created on the basis of a preset objective function and constraint conditions.

The objective function is a function that assumes a combination having a large value as a good combination. In the objective function, for the purpose of user satisfaction, for example, a value of a sum of user satisfaction levels of combinations of recommendations of all users is used. In FIG. 10, (a) is referred to as the user satisfaction level.

The constraint condition is, for example, a condition that a combination that does not satisfy the condition cannot be selected. Thus, it is done. For example, “predicted demand number of a menu−number of recommendations of the menu>0” is used as a constraint condition for preventing recommendations equal to or more than the predicted demand number. Further, “the acceptable number of robots−the number of recommendations including robot delivery>0” is used as a constraint condition for preventing recommendations equal to or more than the acceptable number of robots. In FIG. 10, (b) is referred to for prevention of recommendations equal to or more than the predicted demand number. In FIG. 10, (c) is referred to for prevention of recommendations equal to or more than the acceptable number of robots.

The DTC creates another combination of recommendations and employs a new combination if the value of the objective function improves (increases) and satisfies the constraint condition.

The DTC repeats creation of a combination of recommendations and a new combination until a designated number of times or a designated threshold of an evaluation function is exceeded. The repetition only needs to be used for a method of obtaining a solution of an existing combination optimization problem, and for example, a local search method, a genetic algorithm, or the like is used.

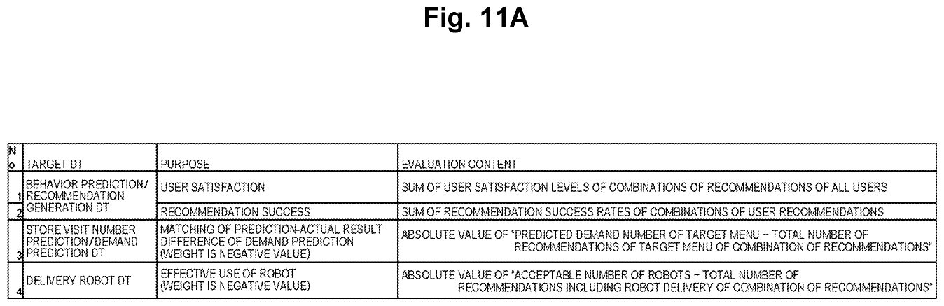

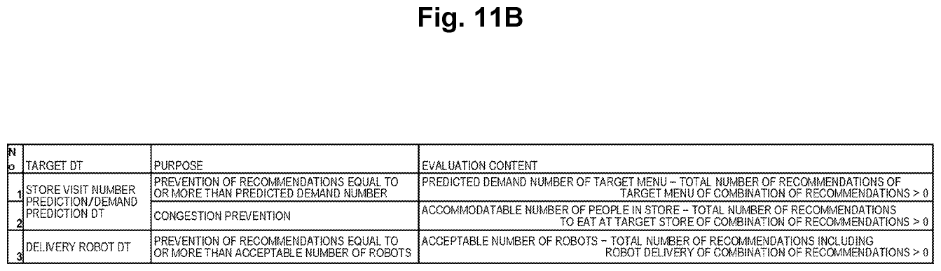

As the contents of the objective function, there are items as illustrated in FIG. 11A in addition to the above example, and an objective function is defined as a weighted sum by selecting an item to be used according to the purpose of the user. The user here is a user of the digital twin system. If the purpose is recommendation success, the sum of recommendation success rates of combinations of user recommendations is used as the evaluation contents. If the purpose is matching of a prediction-actual result difference of demand prediction, an absolute value of “the predicted demand number of the target menu−the total number of recommendations of the target menu of a combination of recommendations” is used as the evaluation contents. If the purpose is effective use of the robot, an absolute value of “the acceptable number of robots−the total number of recommendations including robot delivery of a combination of recommendations” is used as the evaluation contents. As the weight, a negative value is used as appropriate in the matching of the prediction-actual result difference of demand prediction and the effective use of the robot. The objective function is a function obtained by combining one or more purposes described above.

Further, the content of the constraint condition includes items as illustrated in FIG. 11B in addition to the above example, and is used according to the purpose of the user. If the purpose is congestion prevention, “the accommodatable number of people in the store−the total number of recommendations to eat at the target store of combination of recommendations>0” is used as the evaluation contents. If the purpose is to prevent recommendations equal to or more than the acceptable number of robots, “the acceptable number of robots−the total number of recommendations including robot delivery of a combination of recommendations>0” is used as the evaluation contents.

As described above, in a case where the purpose is user satisfaction, a value of the sum of user satisfaction levels of combinations of recommendations of all users is used. In a case where the purpose is recommendation success, the sum of recommendation success rates of combinations of user recommendations is used. In a case where the purpose is matching of the prediction-actual result difference of demand prediction, an absolute value obtained by subtracting the total number of recommendations of a target of a combination of recommendations from the predicted demand number of the target menu is used. For the purpose of effective use of robots, an absolute value obtained by subtracting the total number of recommendations including robot delivery of a combination of recommendations from the acceptable number of robots is used.

Further, in a case where the prevention of recommendations equal to or more than the predicted demand number is set as a constraint, it is set as a constraint that a value obtained by subtracting the number of target recommendations from the target predicted demand number is equal to or more than a predetermined value. In a case where congestion prevention is set as a constraint, it is set as a constraint that a value obtained by subtracting the total number of recommendations to eat at a target store of a combination of recommendations from the accommodatable number of people in the store is equal to or more than a predetermined value. In a case where the prevention of recommendations equal to or more than the acceptable number of robots is set as a constraint, it is set as a constraint that a value obtained by subtracting the total number of recommendations including robot delivery of a combination of recommendations from the acceptable number of robots is equal to or more than a predetermined value.

Note that an example of a method in which the DTC described above creates a combination of recommendations of all users will be described. The DTC is created as a combination that can be assumed to have a large value of the objective function. For example, in a case where the objective function is user satisfaction (the sum of user satisfaction levels of combinations of recommendations of all users), a recommendation having the highest user satisfaction level of each user is selected and a combination is created. Further, an example will be described of a method of creating another combination of recommendations in a case where the DTC described above creates another combination of recommendations, the value of the objective function is improved (increases), and a new combination is employed in a case where the constraint condition is satisfied. The DTC preferentially creates a combination in which recommendations of a user regarding the constraint condition is changed. The user regarding the constraint condition is a user associated with a combination in a case where the constraint condition is not satisfied. For example, in a case where the constraint condition is the “prevention of recommendations equal to or more than the acceptable number of robots”, a recommendation of the user of recommendations including robot delivery is preferentially selected, and a changed combination is created.

In 2-3, the DTC notifies each DT of the result of the overall arbitration.

In 3-1, the behavior prediction/recommendation generation DT notifies the user of the recommendation from the received result of the overall arbitration.

In 3-2, another DT modifies the operation plan from the received result of the overall arbitration. The store visit number prediction/demand prediction DT receives the result of the overall arbitration and modifies the plan. The delivery robot DT receives the result of the overall arbitration and modifies the plan. The air conditioner DT receives the result of the overall arbitration and modifies the plan.

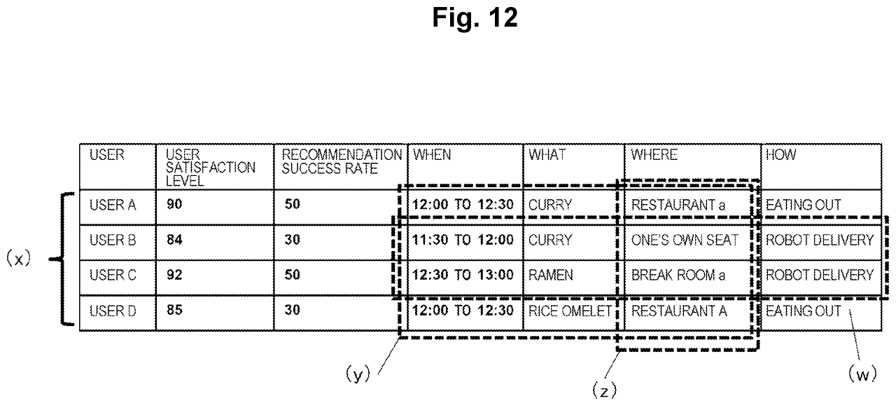

FIG. 12 is an example of a result of the overall arbitration. (x) is a result transmitted to the behavior prediction/recommendation generation DT, and is information to be recommended to each user. (y) is a result transmitted to the store visit number prediction/demand prediction DT, and is the total number of recommendations of each menu. (z) is a result transmitted to the air conditioner DT, and is the total number of people to whom lunch is recommended at each place. (w) is a result transmitted to the delivery robot DT, and is information of recommendations including robot delivery. In this manner, a notification of the content corresponding to each DT is given as the arbitration result from the result of the overall arbitration. Note that, in a case of a partial change to be described later, a notification of the change result is similarly given.

Next, a partial change will be described. In the case of the periodic partial change of FIG. 6, the DTC waits for the periodic activation at 4. In the periodical activation, the process proceeds to 5-1 after a set time (for example, 30 minutes) has elapsed.

In the case of the partial change triggered by the DT in FIG. 7, each DT performs necessity determination of the partial change in 4-1, and notifies the DTC of the partial change request. In the behavior prediction/recommendation generation DT, it is determined that the partial change is “necessary” in a case where the number of users having finished lunch that can be acquired from the user information DB exceeds a preset threshold. A request is made to the DTC, and the process proceeds to 5-1. In the store visit number prediction/demand prediction DT, if a difference between the actual result and the prediction of the number of store visits that can be acquired from the building information DB exceeds a preset threshold, or if the actual sales result number and the predicted number of each menu that can be acquired from the store information DB exceed a preset threshold, it is determined that the partial change is “necessary”. A request is made to the DTC, and the process proceeds to 5-1. The delivery robot DT determines that the partial change is “necessary” if the number of accepted orders exceeds a preset lower limit value or upper limit value. A request is made to the DTC, and the process proceeds to 5-1. The air conditioner DT does not need necessity determination, but may be appropriately performed according to the situation of air conditioning equipment. Note that the example of FIG. 7 is an example of a case where a notification of a request for a partial change is given because necessity determination is “necessary” from the store visit number prediction/demand prediction DT.

In 4-2, the DTC receives a request for a partial change from the DT for which the result of the necessity determination of each DT is “necessary”.

In 5-1, the DTC acquires acquisition information such as the actual result value and the modification plan of the actual result value from each DT. The acquisition information from the behavior prediction/recommendation generation DT is, for example, an actual lunch result. The actual lunch result is a list of recommendation excluded users up to immediately before being acquired and calculated from the user information DB. The excluded user includes, for example, a user who has already finished lunch, a user who is absent in town, and the like. The acquisition information from the store visit number prediction/demand prediction DT is, for example, the actual number of store visitors of each store until immediately before acquired from the building information DB, the predicted value of the number of store visitors in the case of recalculation, the number of demands of each menu until immediately before acquired from the store information DB, and the predicted value of the demand of each menu in the case of recalculation. The acquisition information from the delivery robot DT is, for example, the number of orders that can be accepted at each time after recalculation, and the number of orders that have been accepted until immediately before each time.

In 5-2, the DTC performs calculation of the partial change. The partial change is performed by correcting a difference from the operation plan of the combination of recommendations created in advance, with a combination of recommendations of a result of the overall arbitration or the previous partial change as an initial combination.

The DTC excludes the user on the basis of the recommendation exclusion list received from the behavior prediction/recommendation generation DT. The recommendation exclusion list is a list of excluded users such as users who have finished lunch. The excluded user is not included in the subsequent calculation. The value is obtained on the basis of the objective function and the constraint condition in which the combination is set in advance. The constraint condition here is a function that enables the actual result value to be reflected in the evaluation function of the overall arbitration. An example of the evaluation function in the partial change may be similar to the objective function of the overall arbitration, and an example of the constraint condition in the partial change may be similar to the constraint condition of the overall arbitration. In addition, the repetition condition and the optimization method may be similar to the overall arbitration. In 5-3, the DTC transmits the result of the partial change to each DT. Note that, as the constraint condition reflecting the actual result value, for example, “target predicted demand number−value obtained by subtracting an actual demand result number at the time of target partial change−the number of target recommendations>0” and “number of orders that can be accepted−number of orders that have been accepted−number of recommendations>0” are used.

In 6-1, the behavior prediction/recommendation generation DT notifies the user of the recommendation from the received result of the partial change. Note that the notification contents of 6-1 and 6-2 described later are not illustrated because the values included in the items of the result of the overall arbitration in FIG. 12 have been adjusted.

In 6-2, the operation plan is modified from the result of the partial change received by another DT. The store visit number prediction/demand prediction DT receives the result of the partial change and modifies the plan. The delivery robot DT receives the result of the partial change and modifies the plan. The air conditioner DT receives the result of the partial change and modifies the plan. In addition, each DT operates the object in accordance with the modified plan.

A flowchart of the planning processing in FIG. 8 will be described.

In step S100, the CPU 11 generates a plurality of recommendation candidates and generates an operation plan. As described above, the behavior prediction/recommendation generation DT generates a recommendation candidate, and the other DT generates an operation plan. The processing corresponds to 1-1 and 1-2 described above.

In step S102, the CPU 11 acquires predetermined acquisition information from each DT. A plurality of recommendation candidates is acquired from the behavior prediction/recommendation generation DT, and a constraint/target value is acquired from another DT as acquisition information. This is processing corresponding to 2-1 described above.

In step S104, the CPU 11 creates a combination of recommendations by repetition using a predetermined optimization method in accordance with the objective function and the constraint condition using the acquisition information (step S102), and performs calculation of the overall arbitration. This is processing corresponding to 2-2 described above.

In step S106, the CPU 11 notifies each digital twin of the result of the overall arbitration. This is processing corresponding to 2-3 described above.

In step S108, the CPU 11 executes processing according to the result of the overall arbitration in each digital twin. The processing corresponds to 3-1 and 3-2 described above.

In step S110, the CPU 11 performs the necessity determination in each DT, and notifies the DTC of the partial change request if it is determined that the partial change is necessary. In the case of a periodic partial change, this step is omitted. This is processing corresponding to 4-1 and 4-2 described above.

In step S112, the CPU 11 acquires acquisition information such as the actual result value and the modification plan of the actual result value from each DT. This is processing corresponding to 5-1 described above.

In step S114, the CPU 11 creates a combination of recommendations by correcting a difference from the operation plan of the combination of recommendations created in advance, to thereby perform the calculation of the partial change. The calculation of the partial change is performed using each piece of acquisition information (step S110) from the digital twin, with a combination of recommendations based on the result of the overall arbitration as an initial combination, in accordance with the evaluation function and the constraint condition. This is processing corresponding to 5-2 described above.

In step S116, the CPU 11 notifies each digital twin of the result of the partial change. This is processing corresponding to 5-3 described above.

In step S118, the CPU 11 executes processing according to the result of each partial change in each digital twin. This is processing corresponding to 6-1 and 6-2 described above.

As described above, according to the planning device 10 of the present embodiment, it is possible to create an efficient plan in consideration of mutual influence between digital twins.

Note that the planning processing executed by the CPU reading software (program) in the above embodiment may be executed by various processors other than the CPU. Examples of the processors in this case include a programmable logic device (PLD) whose circuit configuration can be changed after the manufacturing, such as a field-programmable gate array (FPGA), a graphics processing unit (GPU), and a dedicated electric circuit that is a processor having a circuit configuration exclusively designed for executing specific processing, such as an application specific integrated circuit (ASIC). In addition, the planning processing may be executed by one of these various processors, or may be executed by a combination of two or more processors of the same type or different types (for example, a plurality of FPGAs, a combination of a CPU and an FPGA, and the like). In addition, more specifically, a hardware structure of the various processors is an electric circuit in which circuit elements such as semiconductor elements are combined.

In the above embodiment, the aspect in which the planning program is stored (installed) in advance in the storage 14 has been described, but the present invention is not limited thereto. The program may be provided in a form stored in a non-transitory storage medium such as a compact disk read only memory (CD-ROM), a digital versatile disk read only memory (DVD-ROM), or a Universal Serial Bus (USB) memory. Furthermore, the program may be downloaded from an external device via a network.

Regarding the above-described embodiments, the following Supplementary notes are further disclosed.

### (Supplementary Note 1)

A planning device including:
a memory; and
at least one processor connected to the memory, in which
the processor
is the planning device that plans a digital twin system including at least two digital twins, and is configured to
perform calculation of overall arbitration of an operation plan for an operation performed in a state where there is no operation of an object in a real space corresponding to each of the digital twins, and transmit a result of the overall arbitration to each of the digital twins, and
perform calculation of a partial change of the operation plan, by correction based on the result of the overall arbitration, for an operation performed in a state where there is an operation of an object in a real space corresponding to each of the digital twins, and transmit a result of the partial change to each of the digital twins.

### (Supplementary Note 2)

A non-transitory storage medium storing a program executable by a computer to execute planning processing to plan a digital twin system including at least two digital twins, the program including:
performing calculation of overall arbitration of an operation plan for an operation performed in a state where there is no operation of an object in a real space corresponding to each of the digital twins, and transmitting a result of the overall arbitration to each of the digital twins, and
performing calculation of a partial change of the operation plan, by correction based on the result of the overall arbitration, for an operation performed in a state where there is an operation of an object in a real space corresponding to each of the digital twins, and transmitting a result of the partial change to each of the digital twins.

### REFERENCE SIGNS LIST

1 Planning system
10 Planning device
20 Information processing device
102 Overall arbitration unit
104 Partial change unit

1. A planning device for planning a digital twin system including at least two digital twins, the planning device comprising:
a memory; and
at least one processor coupled to the memory, the at least one processor being configured to:
perform calculation of overall arbitration of an operation plan for an operation performed in a state where there is no operation of an object in a real space corresponding to each of the digital twins, and transmit a result of the overall arbitration to each of the digital twins; and
perform calculation of a partial change of the operation plan, by correction based on the result of the overall arbitration, for an operation performed in a state where there is an operation of an object in a real space corresponding to each of the digital twins, and transmit a result of the partial change to each of the digital twins.

2. The planning device according to claim 1, wherein, among a first digital twin related to behavior prediction of a user, a second digital twin related to demand prediction, a third digital twin related to a robot, and a fourth digital twin related to an air conditioner, the digital twin includes at least the first digital twin and the second digital twin,
the at least one processor is configured to create a combination of a recommendation to a user in the first digital twin and a recommendation by a combination of operation plans of other digital twins other than the first digital twin by a predetermined optimization method in accordance with a predetermined objective function and a predetermined constraint condition by using acquisition information from each of the digital twins, and notify each of the digital twins of a result of the overall arbitration, and
create a combination of the recommendations by correcting a difference from an operation plan of a combination of recommendations created in advance using each piece of acquisition information from the digital twins, with the combination of the recommendations based on the result of the overall arbitration as an initial combination, in accordance with a predetermined evaluation function and a predetermined constraint condition, and notify each of the digital twins of a result of the partial change.

3. The planning device according to claim 2, wherein the objective function and the evaluation function represent a function that assumes a combination having a large value as a good combination and further represent a function combining one or more purposes, and
the at least one processor is configured to determine a purpose from any one or a combination of a case where the purpose is user satisfaction, a case where the purpose is recommendation success, a case where the purpose is matching of prediction-actual result difference of demand prediction, and a case where the purpose is effective use of a robot.

4. The planning device according to claim 3, wherein,
in a case where the purpose is the user satisfaction, a value of a sum of user satisfaction levels of combinations of recommendations of all users is used,
in a case where the purpose is the recommendation success, a sum of recommendation success rates of combinations of recommendations of a user is used,
in a case where the purpose is the matching of prediction-actual result difference of demand prediction, an absolute value obtained by subtracting a total number of recommendations of a target of combination of recommendations from a predicted demand number of a target menu is used, and
in a case where the purpose is the effective use of the robot, an absolute value obtained by subtracting a total number of recommendations including robot delivery of a combination of recommendations from an acceptable number of robots is used.

5. The planning device according to claim 2, wherein
the constraint condition is a condition that a combination that does not satisfy a condition is not selectable, and
the at least one processor is configured to determine a constraint from any one or a combination of a case where prevention of recommendations equal to or more than a predicted demand number is set as a constraint, a case where congestion prevention is set as a constraint, a case where prevention of recommendations equal to or more than an acceptable number of robots is set as a constraint, and a case where a value obtained by subtracting a total number of recommendations including robot delivery of a combination of recommendations from an acceptable number of robots being equal to or more than a predetermined value is set as a constraint.

6. The planning device according to claim 5, wherein,
in a case where the prevention of recommendations equal to or more than the predicted demand number is set as a constraint, a value obtained by subtracting a number of target recommendations from a target predicted demand number being equal to or more than a predetermined value is set as a constraint,
in a case where the congestion prevention is set as a constraint, a value obtained by subtracting the total number of recommendations to eat at a target store of a combination of recommendations from an accommodatable number of people in the store being equal to or more than a predetermined value is set as a constraint, and
in a case where the prevention of recommendations equal to or more than an acceptable number of robots is set as a constraint, a value obtained by subtracting a total number of recommendations including robot delivery of a combination of recommendations from an acceptable number of robots being equal to or more than a predetermined value is set as a constraint.

7. A planning method for planning a digital twin system including at least two digital twins, the planning method causing a computer to execute processing comprising:
performing calculation of overall arbitration of an operation plan for an operation performed in a state where there is no operation of an object in a real space corresponding to each of the digital twins, and transmitting a result of the overall arbitration to each of the digital twins; and
performing calculation of a partial change of the operation plan, by correction based on the result of the overall arbitration, for an operation performed in a state where there is an operation of an object in a real space corresponding to each of the digital twins, and transmitting a result of the partial change to each of the digital twins.

8. A non-transitory, computer-readable storage medium storing a planning program for planning a digital twin system including at least two digital twins, the planning program causing a computer to execute processing comprising:
performing calculation of overall arbitration of an operation plan for an operation performed in a state where there is no operation of an object in a real space corresponding to each of the digital twins, and transmitting a result of the overall arbitration to each of the digital twins; and
performing calculation of a partial change of the operation plan, by correction based on the result of the overall arbitration, for an operation performed in a state where there is an operation of an object in a real space corresponding to each of the digital twins, and transmitting a result of the partial change to each of the digital twins.
